(19) United States
(12) Patent Application Publication
(10) Pub. No.: US 2025/0201798 A1
(43) Pub. Date: Jun. 19, 2025

(54) PACKAGE STRUCTURE, DIE STRUCTURE AND METHOD FOR FORMING THE PACKAGE STRUCTURE

(71) Applicant: Taiwan Semiconductor Manufacturing Company, Ltd., Hsinchu (TW)

(72) Inventors: Tsung-Chieh HSIAO, Changhua County (TW); Yu-Bey WU, Hsinchu City (TW)

(73) Assignee: Taiwan Semiconductor Manufacturing Company, Ltd., Hsinchu (TW)

(21) Appl. No.: 18/401,853

(22) Filed: Jan. 2, 2024

Related U.S. Application Data
(60) Provisional application No. 63/610,079, filed on Dec. 14, 2023.

(51) Int. Cl. H01L 25/00; H01L 23/00; H01L 23/48; H01L 25/065; H01L 25/10; H01L 25/18; H10B 80/00

(52) U.S. Cl. CPC H01L 25/50; H01L 23/481; H01L 24/05; H01L 24/08; H01L 24/16; H01L 24/20; H01L 25/0657; H01L 25/105; H01L 25/18; H10B 80/00; H01L 2224/05624; H01L 2224/05639; H01L 2224/05644; H01L 2224/05647; H01L 2224/05655; H01L 2224/05657; H01L 2224/05684; H01L 2224/08145; H01L 2224/16227; H01L 2224/214; H01L 2225/06541; H01L 2225/06548; H01L 2225/06565; H01L 2225/1023; H01L 2225/1041; H01L 2924/1431; H01L 2924/1432; H01L 2924/1433; H01L 2924/1436; H01L 2924/1437

(57) ABSTRACT

A package structure includes an interconnect structure, a first logic die, a molding material, a conductive via, and a redistribution layer. The interconnect structure is attached to a package substrate. The first logic die is disposed over the interconnect structure. The first logic die includes an upper through-silicon via (TSV) on the upper portion of the first logic die and a lower TSV on the lower portion of the first logic die. The upper portion of the first logic die includes a device layer and a power transmission layer, and the upper TSV penetrates through the device layer and physically connected to the power transmission layer. The molding material is over the interconnect structure and surrounds the first logic die. The conductive via penetrates through the molding material. The redistribution layer is over the first logic die and the molding material.

### CROSS REFERENCE TO RELATED APPLICATIONS

This application claims the benefit of U.S. Provisional Application No. 63/610,079, filed Dec. 14, 2023, the entirety of which is incorporated by reference herein.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three-dimensional integrated circuits (3DICs) are a recent development in semiconductor packaging in which multiple semiconductor dies are stacked upon one another, using package-on-package (POP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1C are cross-sectional views illustrating various stages of forming a die structure in accordance with some embodiments of the present disclosure.

FIGS. 2A-2E are cross-sectional views illustrating various stages of forming the die structure in accordance with some embodiments of the present disclosure.

FIGS. 3A-3E are cross-sectional views illustrating various stages of forming a package structure in accordance with some embodiments of the present disclosure.

FIG. 4 is a cross-sectional view illustrating the package structure in accordance with some embodiments of the present disclosure.

FIG. 5A is a schematic top view illustrating the die structure in accordance with some embodiments of the present disclosure.

FIG. 5B is a cross-sectional view illustrating the die structure in accordance with some embodiments of the present disclosure.

FIGS. 6A-6F are cross-sectional views illustrating various stages of forming the package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide package structures, die structures and methods for forming the package structures. The package structure includes a die structure having at least one upper through-silicon via (TSV) and at least one lower TSV. Accordingly, power may be transmitted to devices on opposite sides of the die structure, thereby decreasing the power loss and/or improving the transmission speed of power.

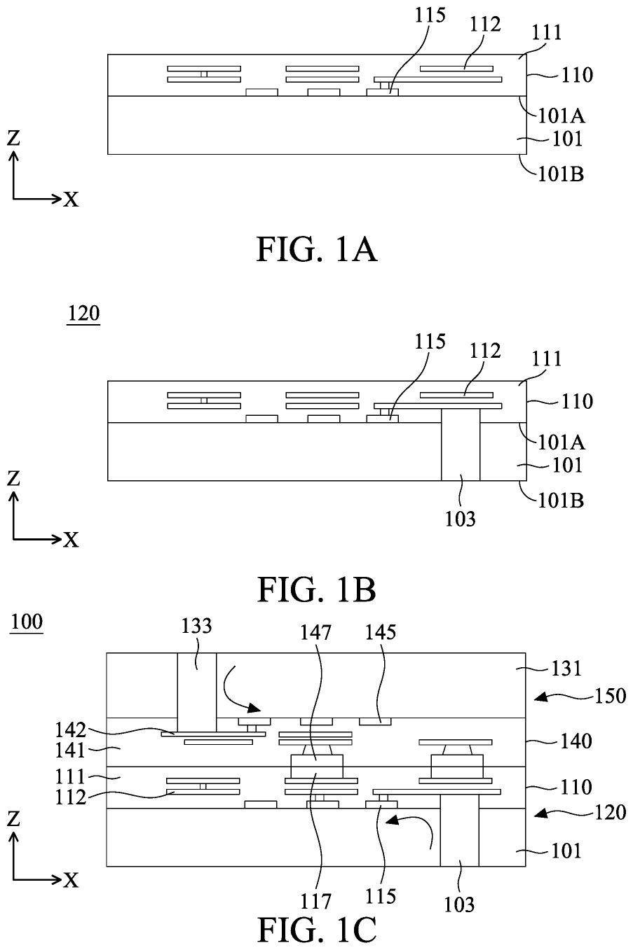

FIGS. 1A-1C are cross-sectional views illustrating various stages of forming a die structure 100 in accordance with some embodiments of the present disclosure. For example, a first substrate 101 includes a semiconductor substrate, including such as silicon, doped or undoped, or an active layer of a silicon-on-insulator (SOI) substrate. In some embodiments, the first substrate 101 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. However, the present disclosure is not limited thereto. Other substrates, such as multi-layered or gradient substrates, may also be used. In some embodiments, the first substrate 101 has an upper surface 101A and a lower surface 101B, in which the lower surface 101B is opposite the upper surface 101A.

In some embodiments, a first device layer 110 may be formed over the first substrate 101. For example, the first device layer 110 may be formed over the upper surface 101A of the first substrate 101. In some embodiments, the first device layer 110 includes a plurality of first dielectric layers 111 and a plurality of first conductive features 112, and the first conductive features 112 are embedded in the first dielectric layers 111. It should be noted that for the sake of brevity, the first dielectric layers 111 are illustrated as single-layered, and the present disclosure is not limited thereto. In addition, the first device layer 110 further includes a plurality of first devices 115 that are disposed over the upper surface 101A of the first substrate 101. In some embodiments, the first devices 115 are surrounded by the first dielectric layers 111 and in contact with the first substrate 101 (for example, the upper surface 101A).

For example, the first dielectric layers 111 include dielectric materials, such as SiO₂, SiN, SiCN, SiOC, SiOCN, or the like. However, the present disclosure is not limited thereto. In some other embodiments, the first dielectric layers 111 include polymers such as polybenzoxazoles (PBO), polyimide (PI), benzocyclobutene (BCB), or the like. The first dielectric layers 111 may be formed, for example, by spin-on coating, chemical vapor deposition (CVD), physical vapor deposition (PVD) or other suitable deposition technique. Other insulation materials formed by any acceptable process may be used. In some embodiments, the first conductive features 112 may include conductive materials. The conductive materials may include metal such as copper, aluminum, nickel, titanium, a combination thereof or other suitable metals.

In some embodiments, the first devices 115 include semiconductor devices that include fin field-effect transistors (FinFETs), for example. Various embodiments may be applied, however, to dies including other types of transistors (e.g., nanostructure field-effect transistors (nanostructure FETs), complementary field effect transistors (CFETs), thin film transistors (TFTs), planar transistors, or the like) in lieu of or in combination with the FinFETs. It should be noted that the present disclosure is not limited thereto. Any possible semiconductor device is included within the scope of the present disclosure.

Next, as shown in FIG. 1B, a first through-silicon via (TSV) 103 is formed in the first substrate 101. The first TSV 103 is electrically connected to the first conductive features 112 in the first device layer 110, and therefore the first TSV 103 may extend into the first device layer 110 and in physical contact with the first conductive features 112. In some embodiments, the first substrate 101 and the first device layer 110 may be flipped to form the first TSV 103. For example, a patterned photoresist layer (not shown) is formed over the lower surface 101B of the first substrate 101. The patterned photoresist layer may be formed by a deposition process and a patterning process. The deposition process for forming the patterned photoresist layer may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process.

In some embodiments, the first substrate 101 is etched to form a first opening (not individually shown) that penetrates through the first substrate 101 via the patterned photoresist layer. The first opening may partially expose the first conductive features 112, which means that the first opening may extend into the first device layer 110 (for example, through the first dielectric layers 111). However, the present disclosure is not limited thereto. Then, a first conductive material is filled into the first opening to form a first TSV 103. The first conductive material may include metal such as copper, aluminum, nickel, titanium, a combination thereof or other suitable metals. Other suitable materials are within the contemplated scope of disclosure. As a result, a first package component 120 is formed.

Although the exemplary process for forming the first TSV 103 is discussed, the present disclosure is not limited thereto. In some other embodiments, the first TSV 103 may be formed in the first substrate 101 prior to forming the first device layer 110 over the first substrate 101. Accordingly, in the embodiments in which the first TSV 103 is formed prior to the first device layer 110, the first conductive features may be formed on the upper surface 101A of the first substrate 101 and in physical contact with the first TSV 103.

Next, as shown in FIG. 1C, the first package component 120 is bonded to a second package component 150 to form a die structure 100, such as, a logic die. In some embodiments, the second package component 150 is formed using the process and material which are the same as those of the first package component 120. For example, the second package component 150 includes a second substrate 131 and a second device layer 140 over the second substrate 131.

In some embodiments, the second device layer 140 includes a plurality of second dielectric layers 141 and a plurality of second conductive features 142, and the second conductive features 142 are embedded in the second dielectric layers 141. It should be noted that, for the sake of brevity, the second dielectric layers 141 are illustrated as single-layered, and the present disclosure is not limited thereto. In addition, the second device layer 140 further includes a plurality of second devices 145 that are disposed over the second substrate 131. In some embodiments, the second devices 145 are surrounded by the second dielectric layers 141 and in contact with the second substrate 131. However, the present disclosure is not limited thereto.

In some embodiments, a second through-silicon via (TSV) 133 is formed in the second substrate 131. The second TSV 133 is electrically connected to the second conductive features 142 in the second device layer 140, and therefore the second TSV 133 may extend into the second device layer 140 and in physical contact with the second conductive features 142. In some embodiments, the second TSV 133 is formed using the method and material which are the same as those of the first TSV 103, but the present disclosure is not limited thereto.

In some embodiments, the first package component 120 and the second package component 150 are bonded via dielectric-to-dielectric bonding and metal-to-metal direct bonding. To be more specific, a plurality of first bonding pads 117 are formed in the first device layer 110 and exposed from the first dielectric layers 111. In some embodiments, the first bonding pads 117 are electrically connected to the first conductive features 112. However, the present disclosure is not limited thereto. For example, the first bonding pads 117 include conductive material such as tungsten (W), cobalt (Co), nickel (Ni), copper (Cu), silver (Ag), gold (Au), aluminum (Al), any other suitable conductive material, or a combination thereof.

Similarly, a plurality of second bonding pads 147 are formed in the second device layer 140 and exposed from the second dielectric layers 141. In some embodiments, the second bonding pads 147 are electrically connected to the second conductive features 142. However, the present disclosure is not limited thereto. For example, the second bonding pads 147 include conductive material such as tungsten (W), cobalt (Co), nickel (Ni), copper (Cu), silver (Ag), gold (Au), aluminum (Al), any other suitable conductive material, or a combination thereof. In some embodiments, each of the first bonding pads 117 of the first device layer 110 are aligned with one of the second bonding pads 147 of the second device layer 140, which is referred to as the metal-to-metal direct bonding. The outermost one of the first dielectric layers 111 are bonded to the outermost one of the second dielectric layers 141, which is referred to as the dielectric-to-dielectric bonding.

It should be noted that, for the sake of clarity, the first package component 120 may be referred to as the lower portion 120 of the die structure 100, and the first TSV 103 may be referred to as the lower TSV 103. Similarly, the second package component 150 may be referred to as the upper portion 150 of the die structure 100, and the second TSV 133 may be referred to as the upper TSV 133.

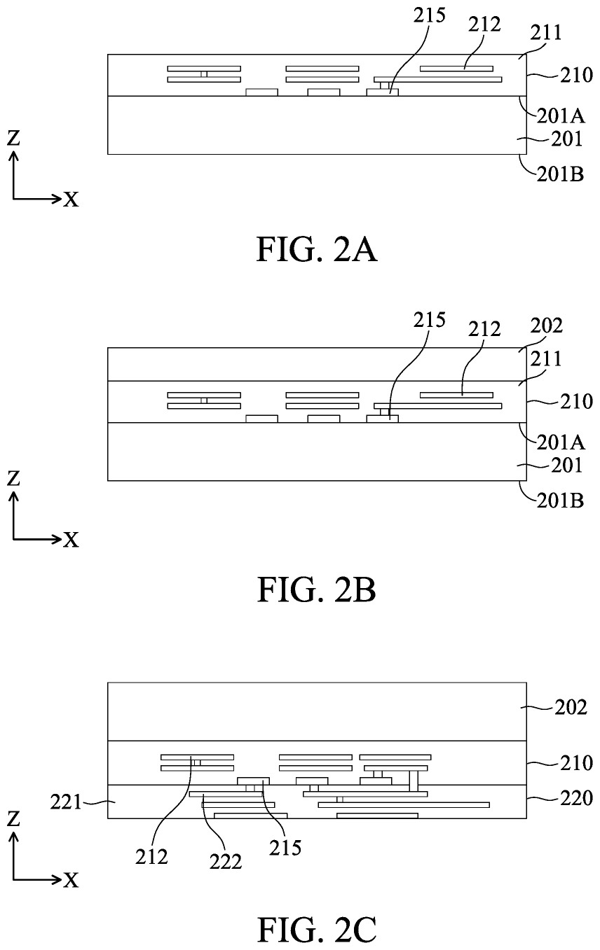

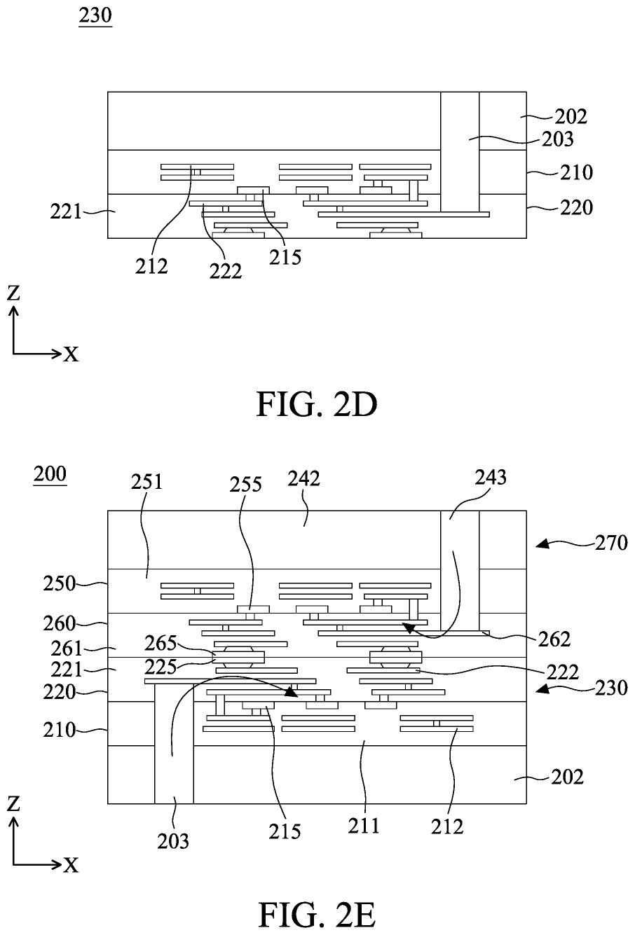

FIGS. 2A-2E are cross-sectional views illustrating various stages of forming a die structure 200 in accordance with some embodiments of the present disclosure. For example, a first substrate 201 includes a semiconductor substrate, including such as silicon, doped or undoped, or an active layer of a silicon-on-insulator (SOI) substrate. In some embodiments, the first substrate 201 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. However, the present disclosure is not limited thereto. Other substrates, such as multi-layered or gradient substrates, may also be used. In some embodiments, the first substrate 201 has an upper surface 201A and a lower surface 201B. The lower surface 201B is opposite the upper surface 201A.

In some embodiments, a first device layer 210 may be formed over the first substrate 201. For example, the first device layer 210 is formed over the upper surface 201A of the first substrate 201. In some embodiments, the first device layer 210 includes a plurality of first dielectric layers 211 and a plurality of first conductive features 212, and the first conductive features 212 are embedded in the first dielectric layers 211. It should be noted that, for the sake of brevity, the first dielectric layers 211 are illustrated as single-layered, and the present disclosure is not limited thereto. In addition, the first device layer 210 further includes a plurality of first devices 215 that are disposed over the upper surface 201A of the first substrate 201. In some embodiments, the first devices 215 are surrounded by the first dielectric layers 211 and in contact with the first substrate 201 (for example, the upper surface 201A).

For example, the first dielectric layers 211 include dielectric materials, such as SiO₂, SiN, SiCN, SiOC, SiOCN, or the like. However, the present disclosure is not limited thereto. In some other embodiments, the first dielectric layers 211 include polymers such as polybenzoxazoles (PBO), polyimide (PI), benzocyclobutene (BCB), or the like. The first dielectric layers 211 may be formed, for example, by spin-on coating, chemical vapor deposition (CVD), physical vapor deposition (PVD) or other suitable deposition technique. Other insulation materials formed by any acceptable process may be used. In some embodiments, the first conductive features 212 may include conductive materials. The conductive materials may include metal such as copper, aluminum, nickel, titanium, a combination thereof or other suitable metals.

In some embodiments, the first devices 215 include semiconductor devices that include fin field-effect transistors (FinFETs), for example. Various embodiments may be applied, however, to dies including other types of transistors (e.g., nanostructure field-effect transistors (nanostructure FETs), complementary field effect transistors (CFETs), thin film transistors (TFTs), planar transistors, or the like) in lieu of or in combination with the FinFETs. It should be noted that the present disclosure is not limited thereto. Any possible semiconductor device is included within the scope of the present disclosure.

Next, as shown in FIG. 2B, a carrier substrate 202 is bonded to the first device layer 210. In some embodiments, at this stage, the first device layer 210 is located between the first substrate 201 and the carrier substrate 202. For example, the carrier substrate 202 may be a wafer (e.g., a silicon wafer), but the present disclosure is not limited thereto. The carrier substrate 202 may provide structural support during subsequent processing steps and in the completed structure.

Then, as shown in FIG. 2C, the first substrate 201 is removed, and a power transmission layer 220 is disposed on the first device layer 210. In some embodiments, at this stage, the first device layer 210 is located between the power transmission layer 220 and the carrier substrate 202. In some embodiments, the power transmission layer 220 is communicated with external power source and supplies power to the first device layer 210. In some embodiments, the power transmission layer 220 includes a plurality of dielectric layers 221 and a plurality of conductive features 222, which are embedded in the dielectric layers 221. It should be noted that, for the sake of brevity, the dielectric layers 221 are illustrated as single-layered, and the present disclosure is not limited thereto.

For example, the dielectric layers 221 include dielectric materials, such as SiO₂, SiN, SiCN, SiOC, SiOCN, or the like. However, the present disclosure is not limited thereto. In some other embodiments, the dielectric layers 221 include polymers such as polybenzoxazoles (PBO), polyimide (PI), benzocyclobutene (BCB), or the like. The dielectric layers 221 may be formed, for example, by spin-on coating, chemical vapor deposition (CVD), physical vapor deposition (PVD) or other suitable deposition technique. Other insulation materials formed by any acceptable process may be used. In some embodiments, the conductive features 222 may include conductive materials. The conductive materials may include metal such as copper, aluminum, nickel, titanium, a combination thereof or other suitable metals.

Next, as shown in FIG. 2D, a first through-silicon via (TSV) 203 is formed through the carrier substrate 202 and the first device layer 210. The first TSV 203 is electrically connected to the conductive features 222 in the power transmission layer 220, and therefore the first TSV 203 may extend into the power transmission layer 220 and in physical contact with the conductive features 222. For example, a patterned photoresist layer (not shown) is formed over the carrier substrate 202. The patterned photoresist layer may be formed by a deposition process and a patterning process. The deposition process for forming the patterned photoresist layer may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process.

In some embodiments, the carrier substrate 202 is etched to form a first opening (not individually shown) that penetrates through the carrier substrate 202 and the first device layer 210 via the patterned photoresist layer. The first opening may partially expose the conductive features 222, which means that the first opening may extend into the power transmission layer 220 (for example, through the dielectric layers 221). However, the present disclosure is not limited thereto. Then, a first conductive material is filled into the first opening to form a first TSV 203. The first conductive material may include metal such as copper, aluminum, nickel, titanium, a combination thereof or other suitable metals. Other suitable materials are within the contemplated scope of disclosure. As a result, a first package component 230 is formed.

Next, as shown in FIG. 2E, the first package component 230 is bonded to a second package component 270 to form a die structure 200, such as, a logic die. In some embodiments, the second package component 270 is formed using the process and material which are the same as those of the first package component 230. For example, the second package component 270 includes a carrier substrate 242, a second device layer 250 over the carrier substrate 242, and a power transmission layer 260 over the second device layer 250. In some embodiments, the second device layer 250 includes a plurality of second dielectric layers 251 and a plurality of second conductive features 252, and the second conductive features 252 are embedded in the second dielectric layers 251. It should be noted that, for the sake of brevity, the second dielectric layers 251 are illustrated as single-layered, and the present disclosure is not limited thereto. In addition, the second device layer 250 further includes a plurality of second devices 255 that are surrounded by the second dielectric layers 251 and in contact with the power transmission layer 260. However, the present disclosure is not limited thereto. In some embodiments, the power transmission layer 260 is communicated with external power source and supplies power to the second device layer 250.

In some embodiments, the first package component 230 and the second package component 270 are bonded via dielectric-to-dielectric bonding and metal-to-metal direct bonding of the power transmission layers 220 and 260. To be more specific, a plurality of first bonding pads 225 are formed in the power transmission layer 220 and exposed from the dielectric layers 221. In some embodiments, the first bonding pads 225 are electrically connected to the conductive features 222. However, the present disclosure is not limited thereto. For example, the first bonding pads 225 include conductive material such as tungsten (W), cobalt (Co), nickel (Ni), copper (Cu), silver (Ag), gold (Au), aluminum (Al), any other suitable conductive material, or a combination thereof.

Similarly, a plurality of second bonding pads 265 are formed in the power transmission layer 260 and exposed from the dielectric layers 261. In some embodiments, the second bonding pads 265 are electrically connected to the conductive features 262. However, the present disclosure is not limited thereto. For example, the second bonding pads 265 include conductive material such as tungsten (W), cobalt (Co), nickel (Ni), copper (Cu), silver (Ag), gold (Au), aluminum (Al), any other suitable conductive material, or a combination thereof. In some embodiments, each of the first bonding pads 225 are aligned with one of the second bonding pads 265, which is referred to as the metal-to-metal direct bonding. The outermost one of the dielectric layers 221 are bonded to the outermost one of the dielectric layers 261, which is referred to as the dielectric-to-dielectric bonding.

It should be noted that, for the sake of clarity, the first package component 230 may be referred to as the lower portion 230 of the die structure 200, and the first TSV 203 may be referred to as the lower TSV 203. Similarly, the second package component 270 may be referred to as the upper portion 270 of the die structure 200, and the second TSV 243 may be referred to as the upper TSV 243.

Although the die structure 100 and the die structure 200 are discussed above, the present disclosure is not limited thereto. It should be noted that, any two of the first package components 120, 230 and the second package components 150, 270 may be arbitrarily combined to form a die structure, and these configurations are included within the scope of the present disclosure. Moreover, the package components 120, 150, 230, and 270 merely serve as examples, any package component with one or more TSV are contemplated within the scope of the present disclosure, as long as the completed die structure has at least one upper TSV and at least one lower TSV.

With the arrangement of the upper TSV (for example, the second TSV 133) and the lower TSV (for example, the first TSV 103), power may be transmitted to the devices (for example, the first device 115 and the second device 145) in the die structure (for example, the die structure 100) more rapidly. To be more specific, power may be transmitted to devices on opposite sides of the die structure (for example, shown as the arrows in FIG. 1C and/or FIG. 2E), thereby decreasing the power loss and/or improving the transmission speed of power. For example, the power may be transmitted through the conductive via, which is wider than the TSVs in the die structure, the power loss may be significantly decreased because the resistance value of the conductive via is less than that of the conductive features in the die structure.

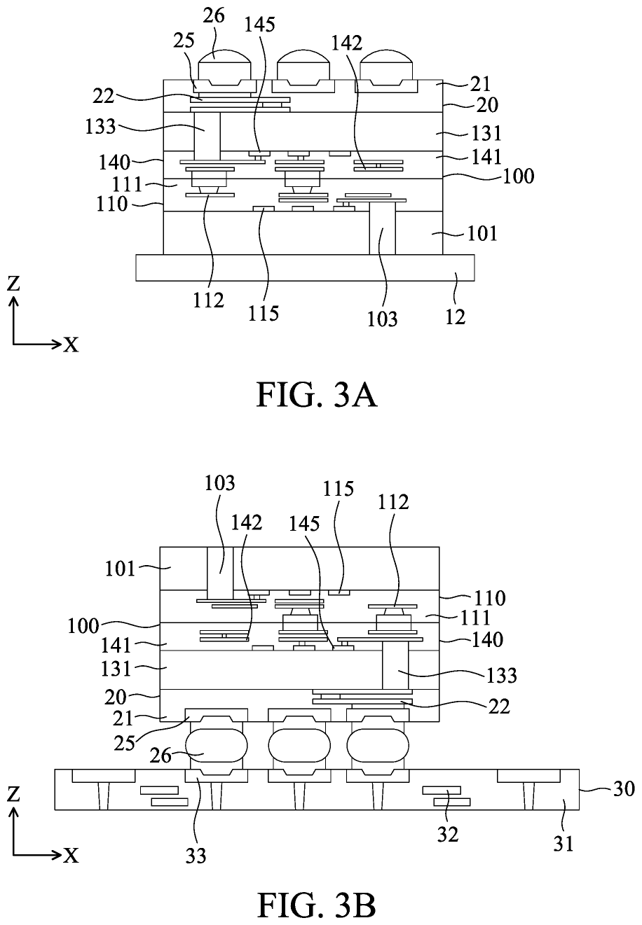

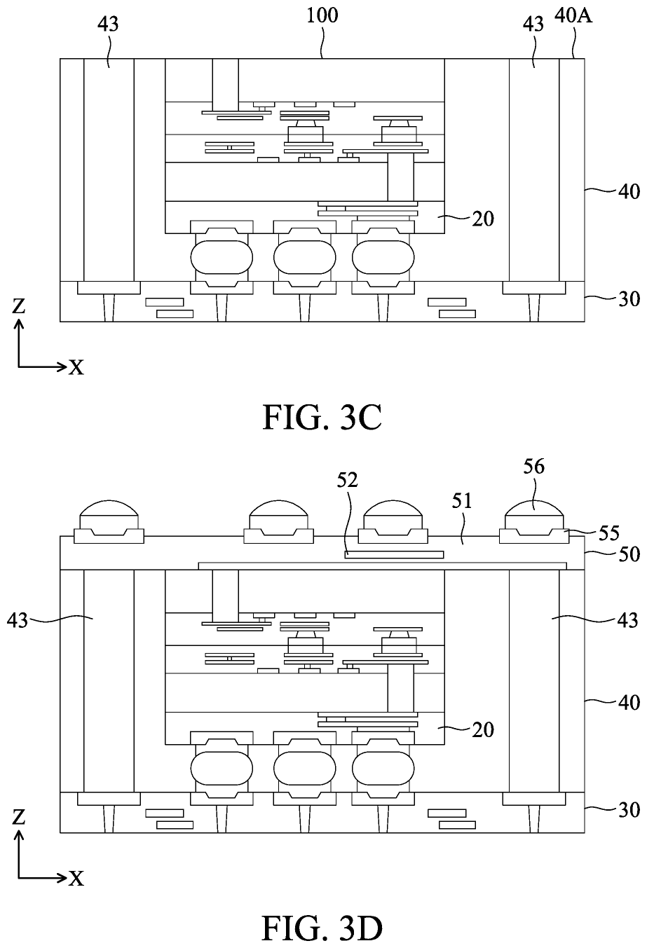

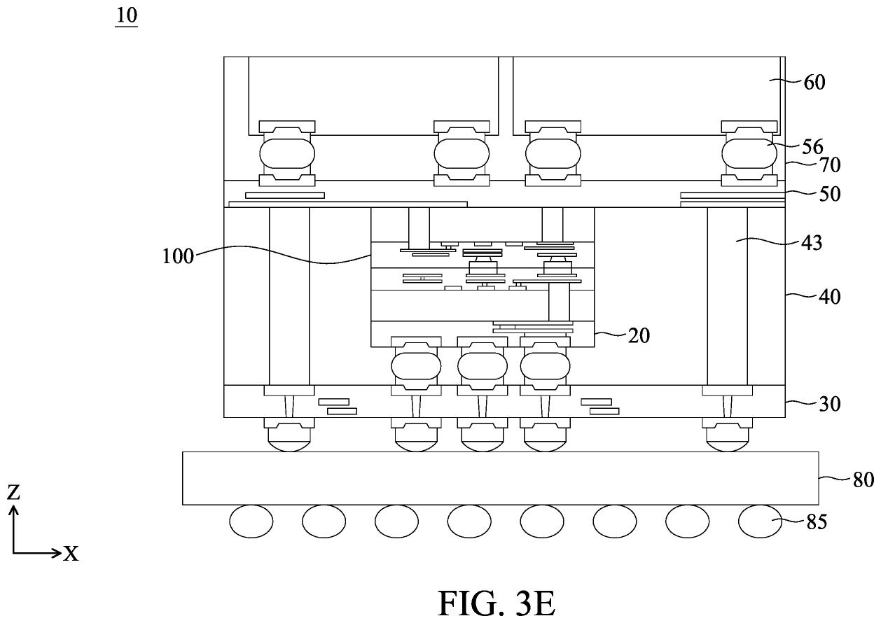

FIGS. 3A-3E are cross-sectional views illustrating various stages of forming a package structure 10 in accordance with some embodiments of the present disclosure. As shown in FIG. 3A, a carrier substrate 12 is provided, and the die structure 100 may be disposed over the carrier substrate 12. For example, the carrier substrate 12 may be a wafer (e.g., a silicon wafer), but the present disclosure is not limited thereto. The carrier substrate 12 may provide structural support for the die structure 100.

In some embodiment, a conductive base 20 is bonded to the die structure 100. The conductive base 20 includes a plurality of dielectric layers 21 and a plurality of conductive features 22, and the conductive features 22 are embedded in the dielectric layers 21. It should be noted that, for the sake of brevity, the dielectric layers 21 are illustrated as single-layered, and the present disclosure is not limited thereto. For example, the dielectric layers 21 include dielectric materials, such as SiO₂, SiN, SiCN, SiOC, SiOCN, or the like. However, the present disclosure is not limited thereto. In some other embodiments, the dielectric layers 21 include polymers such as polybenzoxazoles (PBO), polyimide (PI), benzocyclobutene (BCB), or the like. The dielectric layers 21 may be formed, for example, by spin-on coating, chemical vapor deposition (CVD), physical vapor deposition (PVD) or other suitable deposition technique. Other insulation materials formed by any acceptable process may be used. In some embodiments, the conductive features 22 may include conductive materials. The conductive materials may include metal such as copper, aluminum, nickel, titanium, a combination thereof or other suitable metals. In some embodiments, the conductive features 22 are electrically connected to the die structure 100 via, for example, the second TSV 133.

In addition, as shown in FIG. 3A, under bump metallization (UBM) structures 25 are formed in the dielectric layers 21 of the conductive base 20 and electrically connected to the conductive features 22. The UBM structures 25 may include more layers of copper, nickel, gold, or the like, which are formed by a plating process, or the like. The bump structures 26 are formed on the UBM structures 25. In some embodiments, the bump structures 26 may be conductive ball structures (such as a ball grid array (BGA)), conductive pillar structures, or conductive paste structures that are mounted on and electrically coupled to the conductive base 20 and the die structure 100 in the bonding process. The formation of the bump structures 26 may include placing solder balls on exposed portions of the UBM structures 25 and reflowing the solder balls. In some embodiments, the formation of the bump structures 26 includes performing a plating step to form solder regions over the UBM structures 25 and then reflowing the solder regions. The UBM structures 25 and the bump structures 26 may be used to provide input/output connections to other electrical components, such as, other device dies, redistribution structures, printed circuit boards (PCBs), motherboards, or the like. The UBM structures 25 and the bump structures 26 may provide signal, supply voltage, and/or ground connections to the first devices 115 and the second devices 145 in the die structure 100.

Next, as shown in FIG. 3B, an interconnect structure 30 is bonded to the conductive base 20. For example, the interconnect structure 30 may be an interposer and include a non-organic interposer material, for example, silicon-based dielectric materials such as silicon oxide, porous or non-porous organosilicate glass, silicon carbon nitride, silicon nitride, or any other non-organic interconnect-level dielectric material. However, the present disclosure is not limited thereto.

The interconnect structure 30 includes a plurality of dielectric layers 31 and a plurality of conductive features 32, and the conductive features 32 are embedded in the dielectric layers 31. It should be noted that for the sake of brevity, the dielectric layers 31 are illustrated as single-layered, and the present disclosure is not limited thereto. For example, the dielectric layers 31 include dielectric materials, such as SiO₂, SiN, SiCN, SiOC, SiOCN, or the like. However, the present disclosure is not limited thereto. In some other embodiments, the dielectric layers 31 include polymers such as polybenzoxazoles (PBO), polyimide (PI), benzocyclobutene (BCB), or the like. The dielectric layers 31 may be formed, for example, by spin-on coating, chemical vapor deposition (CVD), physical vapor deposition (PVD) or other suitable deposition technique. Other insulation materials formed by any acceptable process may be used. In some embodiments, the conductive features 32 may include conductive materials. The conductive materials may include metal such as copper, aluminum, nickel, titanium, a combination thereof or other suitable metals. In some embodiments, the conductive features 32 are electrically connected to the die structure 100 via, for example, the bump structures 26.

Furthermore, under bump metallization (UBM) structures 33 are formed in the dielectric layers 31 of the interconnect structure 30 and electrically connected to the conductive features 32. The UBM structures 33 may include more layers of copper, nickel, gold, or the like, which are formed by a plating process, or the like. The bump structures 26 are bonded to the UBM structures 33. Accordingly, the interconnect structure 30 may be bonded to the conductive base 20 via the bump structures 26.

Then, as shown in FIG. 3C, a molding material 40 may be formed on the interconnect structure 30 and around the conductive base 20 and the die structure 100. In some embodiments, the molding material 40 may encapsulate (i.e. cover) the die structure 100 and the conductive base 20 in the horizontal direction (e.g. the X/Y direction). For example, the molding material 40 may include an epoxy polymer material (e.g., an epoxy molding compound (EMC)). The molding material 40 may be formed, for example, by a deposition process such as CVD, PECVD, PVD, spin coating, lamination or other suitable deposition technique. However, the present disclosure is not limited thereto.

For example, a planarization process may be performed on the upper surface 40A of the molding material 40 until the upper surface 40A exposes the top surface of the die structure 100 (for example, the TSV of the die structure 100). In some embodiments, the upper surface 40A of the molding material 40 is substantially level with the top surface of the die structure 100. The planarization process may include, for example, a mechanical grinding process and/or a CMP process.

In addition, at least one (for example, two, as shown in the present embodiment) conductive via 43 is formed through the molding material 40. The conductive vias 43 are electrically connected to the interconnect structure 30, and laterally spaced apart from the die structure 100. In some embodiments, the die structure 100 may be sandwiched between the adjacent conductive vias 43. In some embodiments, the conductive vias 43 may include metal such as copper, aluminum, nickel, titanium, a combination thereof or other suitable metals. Other suitable materials are within the contemplated scope of disclosure. In some embodiments, the conductive vias 43 may be formed by the same material and the same method as the first TSV 103 or the second TSV 133. However, the present disclosure is not limited thereto. In some embodiments, the conductive vias 43 are formed by using material or method that is different from that of the first TSV 103 or the second TSV 133. In some embodiments, the height of the first TSV 103 or the second TSV 133 is different from the height of the conductive via 43 in a vertical direction (for example, the Z direction).

Then, as shown in FIG. 3D, a redistribution layer 50 is disposed over the molding material 40 and the die structure 100. In some embodiments, the redistribution layer 50 includes a plurality of dielectric layers 51 and a plurality of conductive features 52, and the conductive features 52 are embedded in the dielectric layers 51. It should be noted that, for the sake of brevity, the dielectric layers 51 are illustrated as single-layered, and the present disclosure is not limited thereto. For example, the dielectric layers 51 include dielectric materials, such as SiO₂, SiN, SiCN, SiOC, SiOCN, or the like. However, the present disclosure is not limited thereto. In some other embodiments, the dielectric layers 51 include polymers such as polybenzoxazoles (PBO), polyimide (PI), benzocyclobutene (BCB), or the like. The dielectric layers 51 may be formed, for example, by spin-on coating, chemical vapor deposition (CVD), physical vapor deposition (PVD) or other suitable deposition technique. Other insulation materials formed by any acceptable process may be used. In some embodiments, the conductive features 52 may include conductive materials. The conductive materials may include metal such as copper, aluminum, nickel, titanium, a combination thereof or other suitable metals. In some embodiments, the conductive features 52 are electrically connected to the die structure 100 and the conductive vias 43, and therefore power may be supplied to the devices (for example, the first devices 115 and/or the second devices 145) in the die structure 100 via the conductive vias 43 and the conductive features 52.

In addition, under bump metallization (UBM) structures 55 are formed in the dielectric layers 51 of the redistribution layer 50 and electrically connected to the conductive features 52. The UBM structures 55 may include more layers of copper, nickel, gold, or the like, which are formed by a plating process, or the like. The bump structures 56 are formed on the UBM structures 55. In some embodiments, the bump structures 56 may be conductive ball structures (such as a ball grid array (BGA)), conductive pillar structures, or conductive paste structures that are mounted on and electrically coupled to the redistribution layer 50. The formation of the bump structures 56 may include placing solder balls on exposed portions of the UBM structures 55 and reflowing the solder balls. In some embodiments, the formation of the bump structures 56 includes performing a plating step to form solder regions over the UBM structures 55 and then reflowing the solder regions. The UBM structures 55 and the bump structures 56 may be used to provide input/output connections to other electrical components, such as, other device dies, redistribution structures, printed circuit boards (PCBs), motherboards, or the like. The UBM structures 55 and the bump structures 56 may provide signal, supply voltage, and/or ground connections to the first devices 115 and the second devices 145 in the die structure 100.

Next, as shown in FIG. 3E, a plurality of device components 60 are disposed over the redistribution layer 50, and electrically connected to the redistribution layer 50 via, for example, the bump structures 56. For example, the device components 60 may be a device die, a package with a device die(s) packaged therein, a System-on-Chip (SoC) die including a plurality of device dies packaged as a system, or the like. The device components 60 may be or may include logic dies, memory dies, input-output dies, Integrated Passive Devices (IPDs), or the like, or combinations thereof. For example, the logic device dies in the device components 60 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the device components 60 may include Static Random Access Memory (SRAM) dies, Dynamic Random Access Memory (DRAM) dies, or the like. The device components 60 may include semiconductor substrates and interconnect structures, which are not individually shown in the present embodiment. In some embodiments, the die structure 100 may control the operation of the device components 60, and therefore the die structure 100 may also be referred to as “the logic die 100.”

In some embodiments, a molding material 70 may be formed over the redistribution layer 50 and around the device components 60. In some embodiments, the molding material 70 may encapsulate (i.e. cover) the device components 60 in the horizontal direction (e.g. the X/Y direction). For example, the molding material 70 may include an epoxy polymer material (e.g., an epoxy molding compound (EMC)). The molding material 70 may be formed, for example, by a deposition process such as CVD, PECVD, PVD, spin coating, lamination or other suitable deposition technique. However, the present disclosure is not limited thereto.

For example, a planarization process may be performed on the upper surface of the molding material 70 until exposing the top surface of the device components 60. In some embodiments, the upper surface of the molding material 70 is substantially level with the top surface of the device components 60. The planarization process may include, for example, a mechanical grinding process and/or a CMP process. However, the present disclosure is not limited thereto. In some other embodiments, the planarization process may be omitted, and therefore the top surface of the device components 60 may be covered by the molding material 70.

Moreover, a package substrate 80 is bonded to the interconnect structure 30. In some embodiments, the package substrate 80 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 80 includes a layer of a semiconductor material such as epitaxial silicon, germanium, silicon germanium, silicon-on-insulator (SOI), silicon-germanium-on-insulator (SGOI), or combinations thereof. The package substrate 80 is, in one alternative embodiment, based on an insulating core such as a fiberglass reinforced resin core. One example of a core material is fiberglass resin. Alternatives for the core material include bismaleimide-triazine (BT) resin, or alternatively, other PCB materials or films. Build-up films or other laminates may be used for the package substrate 80.

In some embodiments, the package substrate 80 includes bump structures 85. In some embodiments, the bump structures 85 may be conductive ball structures (such as a ball grid array (BGA)), conductive pillar structures, or conductive paste structures that are mounted on and electrically coupled to the package substrate 80 in the bonding process. Accordingly, the package structure 10 is formed. It should be noted that the package structure 10 in the present embodiment merely serves as an example, those skilled in the art should be able to add other components based on the present disclosure to achieve desired functions.

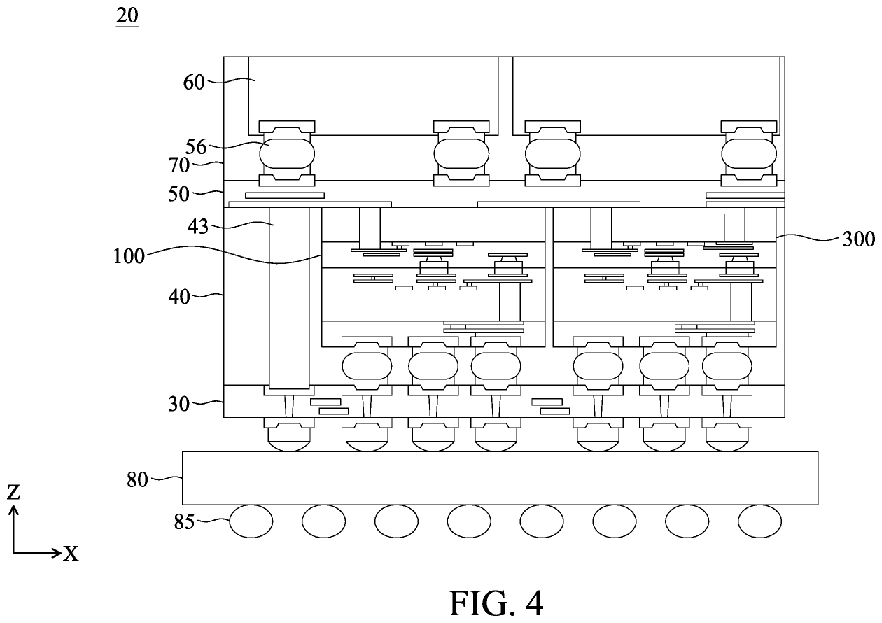

FIG. 4 is a cross-sectional view illustrating the package structure 20 in accordance with some embodiments of the present disclosure. It should be noted that the package structure 20 shown in the present embodiment includes elements that are the same or similar to those of the package structure 10 shown in FIG. 3E. These elements will be denoted using the same numerals for the sake of clarity and simplicity, and will not be discussed in detail again. As shown in FIG. 4, the package structure 20 further includes a die structure 300 that is disposed adjacent to the die structure 100, and the first logic die 100 is sandwiched between the second logic die 300 and the conductive via 43. In order to further distinguish the die structure 100 and the die structure 300, the die structure 100 may be referred to as “the first logic die 100,” and the die structure 300 may be referred to as “the second logic die 300.” In some embodiments, the second logic die 300 includes a plurality of upper TSVs, and the upper TSVs of the second logic die 300 may partially overlap the lower TSV of the second logic die 300. However, the present disclosure is not limited thereto. In some embodiments, the second logic die 300 may be the same as the first logic die 100.

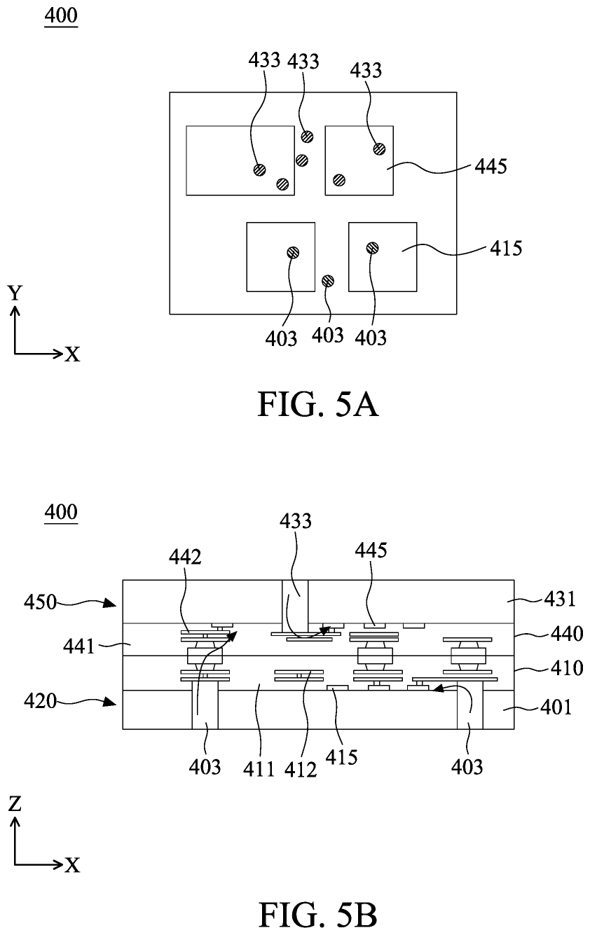

FIG. 5A is a schematic top view illustrating the die structure 400 in accordance with some embodiments of the present disclosure. FIG. 5B is a cross-sectional view illustrating the die structure 400 in accordance with some embodiments of the present disclosure. It should be noted that the die structure 400 shown in the present embodiment includes elements that are the same or similar to those of the die structure 100 shown in FIG. 1C. These elements will be denoted using the same numerals for the sake of clarity and simplicity, and will not be discussed in detail again. As shown in FIGS. 5A and 5B, the die structure 400 is formed by bonding the first package component 420 and the second package component 450. In some embodiments, the first TSVs 403 in the first package component 420 do not overlap the second TSVs 433 in the second package component 450. That is, the first TSVs 403 are offset from the projection region of the second TSVs 433 onto the second substrate 431. However, the present disclosure is not limited thereto.

In some embodiments, the first devices 415 in the first device layer 410 are spaced apart from one of the first TSVs 403 (i.e. the lower TSVs) in the vertical direction (for example, the Z direction). As a result, the design of overall layout of the die structure 400 may be simplified, reducing the cost of formation of the die structure 400. In some embodiments, the first devices 415 in the first device layer 410 each overlap one of the first TSVs 403 (i.e. the lower TSVs) in the vertical direction. As a result, the required space of the die structure 400 may be reduced, miniaturizing the lateral size of the die structure 400.

Similarly, the second devices 445 in the second device layer 440 are spaced apart from one of the second TSVs 433 (i.e. the upper TSVs) in the vertical direction (for example, the Z direction). As a result, the design of overall layout of the die structure 400 may be simplified, reducing the cost of formation of the die structure 400. In some embodiments, the second devices 445 in the second device layer 440 each overlap one of the second TSVs 433 (i.e. the upper TSVs) in the vertical direction. As a result, the required space of the die structure 400 may be reduced, miniaturizing the lateral size of the die structure 400.

It should be noted that, although the present embodiment shows a plurality of first TSVs 403 and a plurality of second TSVs 433, the present disclosure is not limited thereto. The number and locations of the first TSVs 403 and the second TSVs 433 are adjustable based on the present disclosure, as long as at least one first TSV 403 and at least one second TSV 433 are included in the die structure 400.

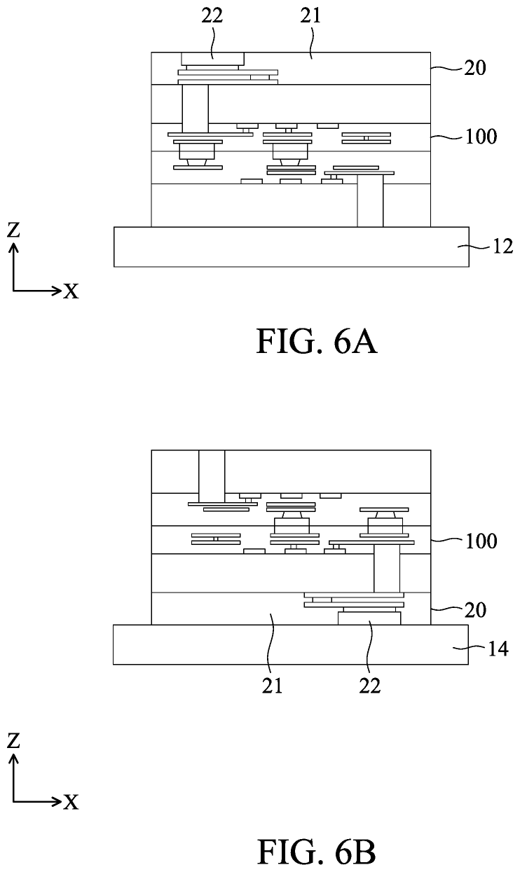

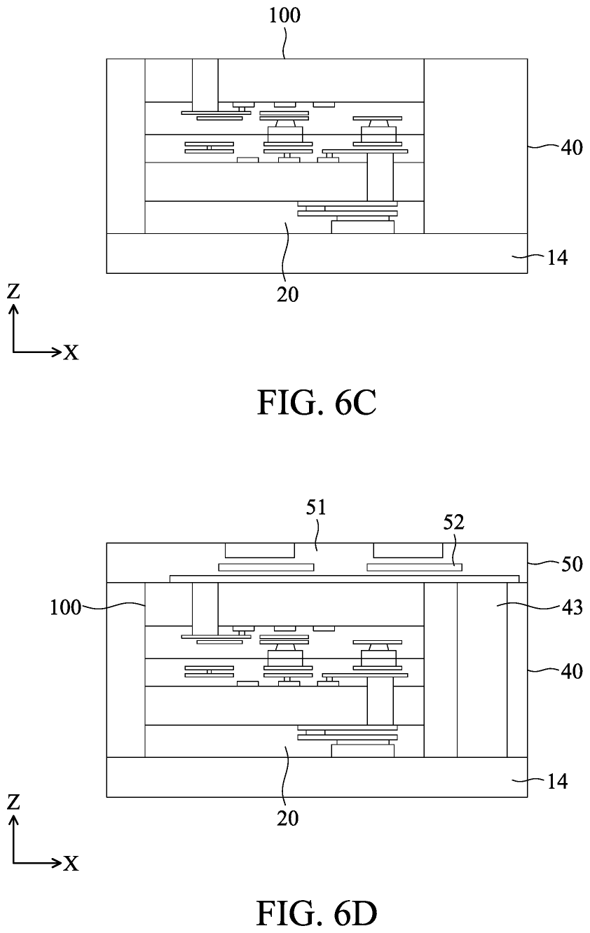

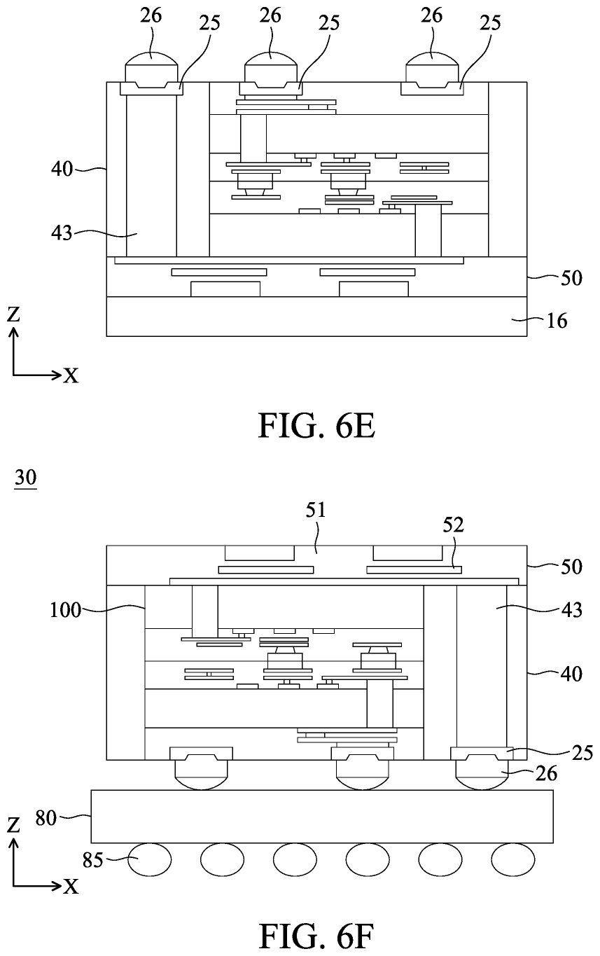

FIGS. 6A-6F are cross-sectional views illustrating various stages of forming a package structure 30 in accordance with some embodiments of the present disclosure. As shown in FIG. 6A, a first carrier substrate 12 is provided, and the die structure 100 may be disposed over the first carrier substrate 12. For example, the first carrier substrate 12 may be a wafer (e.g., a silicon wafer), but the present disclosure is not limited thereto. The carrier substrate 12 may provide structural support for the die structure 100.

In some embodiment, a conductive base 20 is bonded to the die structure 100. The conductive base 20 includes a plurality of dielectric layers 21 and a plurality of conductive features 22, and the conductive features 22 are embedded in the dielectric layers 21. It should be noted that for the sake of brevity, the dielectric layers 21 are illustrated as single-layered, and the present disclosure is not limited thereto. In some embodiments, the conductive features 22 may include conductive materials. The conductive materials may include metal such as copper, aluminum, nickel, titanium, a combination thereof or other suitable metals. In some embodiments, the conductive features 22 are electrically connected to the die structure 100.

Next, as shown in FIG. 6B, a second carrier substrate 14 is provided, and the conductive base 20 may be supported over the second carrier substrate 14. In some embodiments, the conductive base 20 and the die structure 100 are flipped upside down and placed onto the second carrier substrate 14, but the present disclosure is not limited thereto. Any suitable process is included within the scope of the present disclosure, as long as the conductive base 20 faces and is carried by the second carrier substrate 14. For example, the second carrier substrate 14 may be a wafer (e.g., a silicon wafer), but the present disclosure is not limited thereto.

Then, as shown in FIG. 6C, a molding material 40 may be formed on the second carrier substrate 14 and around the conductive base 20 and the die structure 100. In some embodiments, the molding material 40 may encapsulate (i.e. cover) the die structure 100 and the conductive base 20 in the horizontal direction (e.g. the X/Y direction). For example, the molding material 40 may include an epoxy polymer material (e.g., an epoxy molding compound (EMC)). The molding material 40 may be formed, for example, by a deposition process such as CVD, PECVD, PVD, spin coating, lamination or other suitable deposition technique. However, the present disclosure is not limited thereto.

Then, as shown in FIG. 6D, a conductive via 43 is formed through the molding material 40, and a redistribution layer 50 is disposed over the molding material 40 and the die structure 100. The conductive vias 43 are electrically connected to the redistribution layer 50, and laterally spaced apart from the die structure 100. In some embodiments, the conductive vias 43 may include metal such as copper, aluminum, nickel, titanium, a combination thereof or other suitable metals. Other suitable materials are within the contemplated scope of disclosure.

In some embodiments, the redistribution layer 50 includes a plurality of dielectric layers 51 and a plurality of conductive features 52, and the conductive features 52 are embedded in the dielectric layers 51. It should be noted that for the sake of brevity, the dielectric layers 51 are illustrated as single-layered, and the present disclosure is not limited thereto. In some embodiments, the conductive features 52 are electrically connected to the die structure 100 and the conductive vias 43, and therefore power may be supplied to the devices (for example, the first devices 115 and/or the second devices 145) in the die structure 100 via the conductive vias 43 and the conductive features 52.

Next, as shown in FIG. 6E, a third carrier substrate 16 is provided, and the redistribution layer 50 may be supported over the third carrier substrate 16. Any suitable process is included within the scope of the present disclosure, as long as the redistribution layer 50 faces and is carried by the third carrier substrate 16. For example, the third carrier substrate 16 may be a wafer (e.g., a silicon wafer), but the present disclosure is not limited thereto.

In some embodiments, under bump metallization (UBM) structures 25 are formed in the dielectric layers 21 of the conductive base 20 and electrically connected to the conductive features 22. The UBM structures 25 may include more layers of copper, nickel, gold, or the like, which are formed by a plating process, or the like. The bump structures 26 are formed on the UBM structures 25. In some embodiments, the bump structures 26 may be conductive ball structures (such as ball grid array (BGA)), conductive pillar structures, or conductive paste structures that are mounted on and electrically coupled to the conductive base 20 and the die structure 100 in the bonding process.

Then, as shown in FIG. 6F, a package substrate 80 is bonded to the bump structures 26. In some embodiments, the package substrate 80 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 80 includes a layer of a semiconductor material such as epitaxial silicon, germanium, silicon germanium, silicon-on-insulator (SOI), silicon-germanium-on-insulator (SGOI), or combinations thereof. The package substrate 80 is, in one alternative embodiment, based on an insulating core such as a fiberglass reinforced resin core. One example core material is fiberglass resin. Alternatives for the core material include bismaleimide-triazine (BT) resin, or alternatively, other PCB materials or films. Build up films or other laminates may be used for the package substrate 80.

In some embodiments, the package substrate 80 includes bump structures 85. In some embodiments, the bump structures 85 may be conductive ball structures (such as ball grid array (BGA)), conductive pillar structures, or conductive paste structures that are mounted on and electrically coupled to the package substrate 80 in the bonding process. Accordingly, the package structure 30 is formed. It should be noted that the package structure 30 in the present embodiment merely serves as an example, those skilled in the art should be able to add other components based on the present disclosure to achieve desired functions.

Embodiments of the present disclosure provide package structures, die structures and methods for forming the package structures. The package structure includes a die structure having at least one upper through-silicon via (TSV) and at least one lower TSV. Accordingly, power may be transmitted to devices on opposite sides of the die structure, thereby decreasing the power loss and/or improving the transmission speed of power. In some embodiments, the devices in the die structure are spaced apart from the TSVs in the vertical direction, and therefore the design of overall layout of the die structure may be simplified, reducing the cost of formation of the die structure. In some embodiments, the devices in the die structure each overlap one of the TSVs in the vertical direction, and therefore the required space of the die structure may be reduced, miniaturizing the lateral size of the die structure.

In accordance with some embodiments of the present disclosure, a package structure includes an interconnect structure, a first logic die, a molding material, a conductive via, and a redistribution layer. The interconnect structure is attached to a package substrate. The first logic die is disposed over the interconnect structure. The first logic die includes an upper through-silicon via (TSV) on an upper portion of the first logic die and a lower TSV on a lower portion of the first logic die, and the lower TSV is electrically connected to the interconnect structure. The upper portion of the first logic die comprises a device layer and a power transmission layer, and the upper TSV penetrates through the device layer and physically connected to the power transmission layer. The molding material is over the interconnect structure and surrounds the first logic die. The conductive via penetrates through the molding material. The redistribution layer is over the first logic die and the molding material. The redistribution layer is electrically connected to the upper TSV of the first logic die and the conductive via.

In accordance with some embodiments of the present disclosure, a die structure includes a first package component and a second package component. The first package component includes a first TSV in a first substrate, a first device layer over the first substrate, and a first power transmission layer over the first device layer. The first TSV extends into the first power transmission layer. The first device layer includes a plurality of first devices, and the first devices are electrically connected to the first TSV. The second package component includes a second TSV in a second substrate, a second device layer over the second substrate, and a second power transmission layer over the second device layer. The second device layer includes a plurality of second devices, and the second devices are electrically connected to the second TSV. The first device layer is bonded to the second device layer via dielectric-to-dielectric bonding and metal-to-metal direct bonding of the first power transmission layer and the second power transmission layer.

In accordance with some embodiments of the present disclosure, a method of forming a package structure includes forming a first package component, which includes forming a first device layer over a first substrate; forming a power transmission layer over the first device layer; etching the first substrate to form a first opening; and filling the first opening with a first conductive material to form a first TSV. The first opening extends into the first substrate, the first device layer, and the power transmission layer. The method also includes forming a second package component, which includes forming a second device layer over a second substrate; etching the second substrate to form a second opening; and filling the second opening with a second conductive material to form a second TSV. The method further includes bonding the first package component and the second package component to form a first logic die. The first package component and the second package component are bonded via dielectric-to-dielectric bonding and metal-to-metal direct bonding. The method includes disposing the first logic die over an interconnect structure, and forming a molding material over the interconnect structure and around the first logic die. The method further includes forming a first conductive via to penetrate through the molding material, and forming a redistribution layer over the first logic die and the molding material. The redistribution layer is electrically connected to the first TSV of the first logic die and the first conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
an interconnect structure attached to a package substrate;
a first logic die disposed over the interconnect structure, wherein the first logic die comprises an upper through-silicon via (TSV) at an upper portion of the first logic die and a lower TSV at a lower portion of the first logic die, and the lower TSV is electrically connected to the interconnect structure, wherein the upper portion of the first logic die comprises a device layer and a power transmission layer, and the upper TSV penetrates through the device layer and physically connected to the power transmission layer;
a molding material surrounding the first logic die;
a conductive via penetrating through the molding material; and
a redistribution layer over the first logic die and the molding material, wherein the redistribution layer is electrically connected to the upper TSV of the first logic die and the conductive via.

2. The package structure as claimed in claim 1, wherein the molding material exposes the upper TSV of the first logic die.

3. The package structure as claimed in claim 1, wherein the first logic die further comprises:
a first substrate, wherein the lower TSV penetrates through the first substrate; and
a second substrate, wherein the upper TSV penetrates through the second substrate.

4. The package structure as claimed in claim 3, wherein a device in the device layer is spaced apart from the upper TSV in a vertical direction.

5. The package structure as claimed in claim 3, wherein a height of the upper TSV is different from a height of the conductive via in a vertical direction.

6. The package structure as claimed in claim 1, further comprising a second logic die disposed adjacent to the first logic die and electrically connected to the conductive via.

7. The package structure as claimed in claim 1, further comprising a device component over the redistribution layer.

8. A die structure, comprising:
a first package component, comprising:
a first TSV in a first substrate;
a first device layer over the first substrate, wherein the first device layer comprises a plurality of first devices, and the first devices are electrically connected to the first TSV; and
a first power transmission layer over the first device layer, wherein the first TSV extends into the first power transmission layer; and
a second package component, comprising:
a second TSV in a second substrate;
a second device layer over the second substrate, wherein the second device layer comprises a plurality of second devices, and the second devices are electrically connected to the second TSV; and
a second power transmission layer over the second device layer,
wherein the first device layer is bonded to the second device layer via dielectric-to-dielectric bonding and metal-to-metal direct bonding of the first power transmission layer and the second power transmission layer.

9. The die structure as claimed in claim 8, wherein the first device layer further comprises a plurality of first bonding pads, the second device layer further comprises a plurality of second bonding pads, and each of the first bonding pads are aligned with one of the second bonding pads of the second device layer.

10. The die structure as claimed in claim 8, wherein the first devices are in contact with the first substrate.

11. The die structure as claimed in claim 8, wherein the second TSV penetrates through the second device layer.

12. The die structure as claimed in claim 11, wherein the first TSV is offset from a projection region of the second TSV onto the second substrate.

13. A method of forming a package structure, comprising:
forming a first package component, comprising:
forming a first device layer over a first substrate;
forming a power transmission layer over the first device layer;
etching the first substrate to form a first opening, wherein the first opening extends into the first substrate, the first device layer, and the power transmission layer; and
filling the first opening with a first conductive material to form a first TSV;
forming a second package component, comprising:
forming a second device layer over a second substrate;
etching the second substrate to form a second opening; and
filling the second opening with a second conductive material to form a second TSV;
bonding the first package component and the second package component to form a first logic die, wherein the first package component and the second package component are bonded via dielectric-to-dielectric bonding and metal-to-metal direct bonding;
disposing the first logic die over an interconnect structure;
forming a molding material over the interconnect structure and around the first logic die;
forming a first conductive via to penetrate through the molding material; and
forming a redistribution layer over the first logic die and the molding material,
wherein the redistribution layer is electrically connected to the first TSV of the first logic die and the first conductive via.

14. The method as claimed in claim 13, wherein the first device layer comprises a plurality of first dielectric layers and a plurality of first conductive features, and the first conductive features are embedded in the first dielectric layers.

15. The method as claimed in claim 13, wherein the molding material exposes the first TSV of the first logic die from a top surface of the molding material, and the top surface of the molding material is farther from the interconnect structure than a bottom surface of the molding material.

16. The method as claimed in claim 13, further comprising:
forming a second conductive via to penetrate through the molding material, wherein the first logic die is located between the first conductive via and the second conductive via.

17. The method as claimed in claim 13, further comprising:
disposing a second logic die over the interconnect structure, wherein the second logic die is surrounded by the molding material, and the first logic die is located between the second logic die and the first conductive via.

18. The method as claimed in claim 13, further comprising:
forming a plurality of bump structures on the redistribution layer, wherein the bump structures are electrically connected to the first conductive via.

19. The method as claimed in claim 18, further comprising:
disposing a device die over the bump structures, wherein the device die is electrically connected to the bump structures.

20. The method as claimed in claim 13, further comprising:
bonding the interconnect structure to a package substrate after forming the redistribution layer over the first logic die and the molding material.
